(19) United States
(12) Patent Application Publication
(10) Pub. No.: US 2026/0123308 A1
(43) Pub. Date: Apr. 30, 2026

(54) ULTRA-LOW TEMPERATURE SILICON MOLECULAR BEAM EPITAXY USING DOPANT-INDUCED CATALYSIS OF HYDROGEN-TERMINATED SILICON

(71) Applicant: California Institute of Technology, Pasadena, CA (US)

(72) Inventors: Michael E. Hoenk, Valencia, CA (US); April D. Jewell, Los Angeles, CA (US)

(73) Assignee: California Institute of Technology, Pasadena, CA (US)

(21) Appl. No.: 19/369,006

(22) Filed: Oct. 24, 2025

Related U.S. Application Data
(60) Provisional application No. 63/711,606, filed on Oct. 24, 2024.

(51) Int. Cl. H10P 32/14; C30B 23/00; C30B 23/02; C30B 29/06; C30B 29/68; H10D 62/40; H10D 62/83; H10P 14/20

(52) U.S. Cl. CPC H10P 32/14; C30B 23/005; C30B 23/025; C30B 29/06; C30B 29/68; H10D 62/405; H10D 62/83; H10P 14/3411

(57) ABSTRACT

A method for fabricating a device, including epitaxially depositing dopants on a (001) surface of a silicon wafer; and epitaxially depositing one or more crystalline silicon layers on the surface so as to encapsulate the dopants.

### CROSS REFERENCE TO RELATED APPLICATIONS

This application claims the benefit under 35 U.S.C. Section 119(e) of U.S. Provisional Application No. 63/711,606 filed Oct. 24, 2024, by Michael E. Hoenk and April D. Jewell, entitled “Ultra-Low Temperature Silicon Molecular Beam Epitaxy Using Dopant-Induced Catalysis of Hydrogen-Terminated Silicon,” (CIT-8893-P3), which application is incorporated by reference herein.

### STATEMENT REGARDING FEDERALLY SPONSORED RESEARCH AND DEVELOPMENT

This invention was made with government support under Grant No. 80NM0018D0004 awarded by NASA (JPL). The government has certain rights in the invention

### BACKGROUND OF THE INVENTION

### 1. Field of the Invention

The field of this invention is surface passivation of silicon detectors for improved performance and higher manufacturing yield.

### 2. Description of the Related Art

Many applications may benefit from efficient silicon detectors, including in particular silicon charge-coupled devices (CCDs) and Complementary Metal Oxide Semiconductor (CMOS) Image Sensors. Silicon CCDs and CMOS image sensors have been transformational in applications spanning such diverse fields as astronomy, space science, earth-observing satellites, planetary science, high energy physics, electron microscopy, machine vision, silicon integrated circuit manufacturing, and commercial cell phones. The response of silicon detectors may be extended beyond the visible by thinning and back illumination, but such devices should be fabricated with passivation of defects and traps at surfaces and interfaces and with high yield. The present disclosure satisfies this need.

### SUMMARY OF THE INVENTION

Illustrative embodiments of the inventive subject matter disclosed herein include, but are not limited to, the following.

1. A method for fabricating a device, comprising:
(a) epitaxially depositing dopants on a (001) surface of a silicon wafer; and
(b) epitaxially depositing a crystalline silicon layer on the surface so as to encapsulate the dopants.

2. The method of clause 1, wherein the dopants and the silicon are deposited at a temperature below 425 degrees Celsius, e.g., wherein the dopants catalyze a transformation of the (001) surface into a surface that supports the subsequent epitaxial growth of silicon

3. The method of clause 1 or 2, wherein the temperature of the depositing in (a) and (b) is 400 degrees Celsius or less.

4. The method of clause 1 or 2, wherein the temperature of the depositing in (a) and (b) is 370 degrees Celsius or less.

5. The method of clause 1 or 2, wherein the temperature of the depositing in (a) and (b) is 350 degrees Celsius or less.

6. The method of any of the clauses 1-5, wherein between 0.5 monolayer and less than 1 monolayer (or 0.6 monolayer or less) of the dopants are deposited on the (001) surface, or wherein at least 0.1 monolayer or wherein at least 0.5 monolayer of the dopants are deposited on the (001) surface.

7. The method of any of the clauses 1-6, wherein the dopants forms bonds with the silicon so as to facilitate desorption of hydrogen from the hydrogen-terminated silicon surface and/or passivation of the contaminants or defects at the (001) surface.

8. The method of any of the clauses 1-7, wherein the (001) surface is a disordered or rough surface and the dopants are deposited directly on the disordered or rough surface.

9. The method of clause 8, wherein the dopants provide a charge that passivates the charge traps introduced by the contaminants or defects at and/or near the (001) surface.

10. The method of clause 9, further comprising depositing a plurality of the silicon layers alternating with layers of the dopants, so as to form a stack comprising multilayer delta doping.

11. The method of clause 10, wherein the device comprises a surface passivation layer entirely fabricated at a temperature below 425° C. and having a dark current that is reduced as compared that of the otherwise identical device fabricated using a temperature greater than 425° C.

12. The method of any of the clauses 1-11, further comprising passivating a plurality of the devices on the silicon wafer at the temperature below 425° C., wherein the manufacturing yield is greater as compared to the otherwise identical devices fabricated at a temperature greater than 425° C., wherein the greater yield includes less delamination of the silicon wafer from a support wafer present during the depositing.

13. The method of any of the clauses 1-12, wherein the dopants comprise p-type dopants for silicon (e.g., boron) or n-type dopants for silicon (e.g., antimony or phosphorous).

14. A passivated silicon structure, comprising:
(a) a substrate with a silicon (001) surface,
(b) a layer of dopants (e.g, n-type or p-type) in direct physical contact with the silicon (001) surface; and
(c) a crystalline silicon layer epitaxially grown directly on the silicon (001) surface encapsulating the dopants.

15. The passivated silicon structure of clause 14, wherein the crystalline silicon layer comprises one or more delta-doped layers.

16. The passivated silicon structure of clause 14 or 15, comprising one or more devices.

17. The passivated silicon structure of any of the clauses 14-16, comprising one or more back-thinned silicon devices.

18. The passivated silicon structure of any of the clauses 14-17, wherein the layer of dopants comprises at least 0.1 monolayer of the dopants.

19. The passivated silicon structure of any of the clauses 14-17, wherein the layer of dopants comprises at least 0.5 monolayer of the dopants.

20. The device of any of the clauses 14-19, wherein a surface density of the dopants passivates traps located near the substrate-epitaxial silicon interface.

21. The device of any of the clauses 14-20, wherein the silicon (001) surface is a disordered surface.

22. The device of any of the clauses 14-21 manufactured by the method of any of the clauses 1-13.

23. The device of any of the clauses wherein the dopants deposited on the (001) surface delta dope the silicon (001) surface to form 2D doped silicon.

### BRIEF DESCRIPTION OF THE DRAWINGS

Referring now to the drawings in which like reference numbers represent corresponding parts throughout:

FIG. 1. Flowchart illustrating a method of making a device.

FIG. 2A. Schematic of a passivated silicon structure according to one or more embodiments (thicknesses not shown to scale).

FIG. 2B. Schematic of a conventional device fabricated using a buffer layer (thicknesses not shown to scale).

FIG. 2C. Schematic illustrating encapsulation of dopants (thicknesses not shown to scale), wherein further delta doped layers can be grown on top as illustrated in FIG. 2A.

FIG. 2D illustrates an implementation wherein the passivated silicon structure is bonded to a support substrate (thicknesses not shown to scale).

FIG. 3A-3B. Reflection High Energy Electron Diffraction (RHEED) measurements at various temperatures of epitaxial growth for the sample having a low resistivity substrate having 100 mm diameter with resistivity 0-100 ohm-cm and <100> orientation. The presence of the reconstruction lines demonstrates the functioning of the process of epitaxial growth of silicon at low temperature. Pre-deposition indicates the silicon (001) surface prior to deposition of dopants, and Post-deposition indicates the silicon surface after deposition of the dopants and encapsulating the dopants with growth of epitaxial silicon.

FIG. 4. RHEED measurements at various temperatures of epitaxial growth for the sample having a high resistivity substrate having a 150 mm diameter with resistivity >10,000 Ohm and <100> orientation (Experiment 1). While the reconstruction lines are faint in the 350° C. sample, their presence together with the conductivity data demonstrates the functioning of the process of epitaxial growth of silicon at low temperature. Pre-deposition indicates the silicon (001) surface prior to deposition of dopants, and Post-deposition indicates the silicon surface after deposition of the dopants and encapsulating the dopants with growth of epitaxial silicon.

FIG. 5 illustrates an example back thinned detector.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

Various disclosed embodiments may include a 2D-doped silicon layer for surface passivation of back-illuminated CCDs, CMOS image sensors or other silicon devices. The structure of 2D-doped silicon comprises crystalline silicon incorporating one or more layers of delta-doped silicon, and may be referred to as 2D-doped, delta-doped, or multilayer doped silicon in various contexts. The 2D-doped silicon structure may be formed by a low temperature molecular beam epitaxial (MBE) growth process. These image sensors may include high charge collection efficiency with exceptional stability in various environments, including but not limited to, space and other harsh environments. Lifetime tests performed on 2D-doped CMOS image sensors using pulsed DUV lasers have demonstrated the unique stability of 2D-doped detectors against high levels of radiation-induced surface damage. The image sensors include delta-doped silicon grown by MBE on the illuminated surface for reflection-limited UV quantum efficiency. Image sensors including a grown delta-doped silicon layer are described in U.S. Pat. No. 5,376,810, entitled “Growth of delta-doped layers on silicon CCDs for enhanced ultraviolet response” and filed Dec. 21, 1993, which is hereby incorporated by reference in its entirety for all purposes [1]. Further, image sensors including a grown delta-doped silicon layer are described in U.S. Pat. No. 8,395,243, entitled “Surface passivation by quantum exclusion using multiple layers” and filed Jun. 15, 2011, which is hereby incorporated by reference in its entirety for all purposes [2]. Further, image sensors including a grown delta-doped silicon layer are described in U.S. Pat. No. 9,024,344, entitled “Surface passivation by quantum exclusion using multiple layers” and filed Mar. 8, 2013, which is hereby incorporated by reference in its entirety for all purposes [3]. Further, image sensors including a grown delta-doped silicon layer are described in U.S. Pat. No. 8,828,852, entitled “Delta-doping at wafer level for high throughput, high yield fabrication of silicon imaging arrays” and filed Dec. 10, 2010, which is hereby incorporated by reference in its entirety [4].

In growing a delta-doped layer, epitaxial layers of crystalline silicon may be grown on a fully-processed, back-thinned CCD or CMOS image sensor. Delta-doped CCDs and CMOS image sensors may contain an exceptionally high density of an electrically-active dopant such as boron (e.g. 2×10¹⁴ B/cm²) in a single layer of the silicon crystal, which may enable stable, uniform, reflection-limited quantum efficiency (QE). Delta-doped CCDs and CMOS image sensors may remain stable over a period of years independent of environmental conditions. The image sensors including delta-doped silicon may exhibit near 100% internal QE in the soft X-ray and extreme ultra-violet (EUV) spectral range. An MBE crystalline growth process may produce a multi-layered delta doped crystalline layer with one or more delta-doped layers separated by layers of crystalline silicon. The separating layers comprise crystalline silicon that may be intrinsic or may incorporate a finite concentration of randomly distributed dopant atoms (sometimes referred to as 3D-doped silicon). The delta-doped layer(s) may include dopant atoms arranged in a two-dimensional (2D) layer to achieve greater than 10× higher free carrier density than similar dopant concentrations distributed over a three-dimensional region [5,6]. Producing the multi-layered, delta-doped, crystalline structure may include alternately and cyclically contacting the sensor surface with a source including silicon and a source including dopants.

### Low Temperature Cleaning Processes

The manufacture of 2D-doped image sensors requires a cleaning process to remove damage and contaminants and to prepare the surface for growth of a 2D-doped silicon passivation layer. The maximum temperature of the cleaning process is a critical parameter because excessive heating can cause structural damage and degraded performance in silicon devices. In the prior art it was known that process temperatures greater than 450° C. can damage silicon CCDs and CMOS image sensors because metallic aluminum reacts with silicon at high temperatures. Grunthaner et al. developed a low temperature cleaning process that removes silicon oxide and terminates silicon surface with hydrogen and then bakes the silicon surface in an ultrahigh vacuum system using a ramped temperature profile to evaporate physisorbed contaminants [7]. The maximum temperature used in the Grunthaner et al. process is 450° C., which is sufficient to enable the growth of delta-doped silicon using MBE [1].

Eaglesham et al. [8] developed a 370° C. cleaning process, and showed that their process enables epitaxial growth of high quality silicon at temperatures as low as 380° C.; however, Eaglesham et al. never used their low temperature cleaning to grow delta-doped silicon. The silicon MBE research group at AT&T Bell Laboratories (in a collaboration that included D. J. Eaglesham, R. L. Headrick and H.-J. Gossmann) developed a low temperature delta-doping process as a means to solving the doping problem in silicon MBE [9], wherein delta-doped silicon layers comprise ordered monolayer structures in Si(111) and Si(100) [10] and self-limited monolayer doping [11]. Whereas the AT&T process for growing delta-doped silicon on Si(100) substrates used low temperature MBE to avoid thermal diffusion of dopants during processing, their process for cleaning and surface preparation of substrates at high temperatures. The AT&T surface preparation process includes heating the substrate to 800° C., depositing 1.5 nm of silicon at 800° C. to desorb the oxide, followed by growth of a 30 nm silicon buffer layer, and finally cooling the substrate to lower temperatures for the growth of delta-doped silicon layers [9,10,11].

### Growth of Delta-Doped Silicon on Silicon Surfaces Cleaned at Low-Temperatures

Epitaxial growth of silicon on surfaces cleaned at low temperatures is highly dependent on the density of defects and contaminants either on or beneath the cleaned surface. Low temperature cleaning processes are known to produce significantly higher densities of surface defects, chemisorbed hydrogen, and contaminants compared to high temperature cleaning processes.

The requirement for low densities of defects and contaminants places stringent requirements on low temperature cleaning processes, especially for low temperature cleaning processes developed for surface passivation of silicon devices.

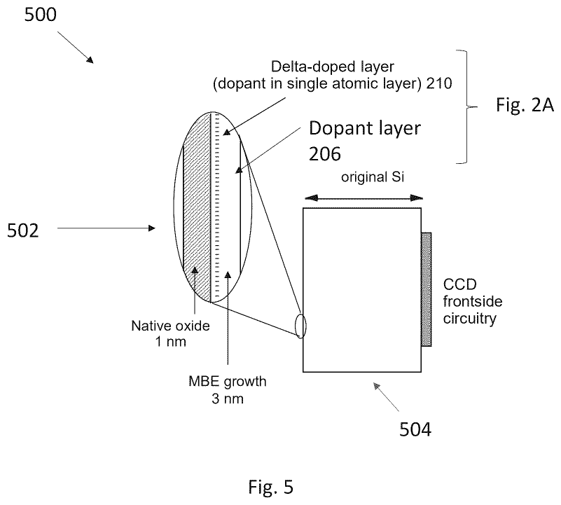

At the same time, the growth of delta-doped silicon requires the formation of an ordered, atomically clean Si(100) surface. In previous work, JPL has found that growing delta-doped layers on silicon detectors requires heating the detector surface to at least 425° C. using a low temperature HF:ethanol spin-clean process according to Grunthaner et al. [7]. Citing JPL's prior work in this field, MIT Lincoln Laboratories (MIT-LL) used a low temperature cleaning process very similar to the process developed by Grunthaner et al. to passivate back-illuminated CCDs. In their 2002 paper reporting on this work, MIT-LL stated that active incorporation of the boron dopant and minimum density of electron trapping defects requires performing MBE growth of highly-doped silicon at the highest possible growth temperature for silicon devices, which they identify as the 450° C. temperature used in their process [12]. MIT-LL further state that epitaxial growth on Si(100) requires a transformation of the surface structure from 1×1 RHEED reconstruction pattern to a 2×1 reconstruction pattern [see FIG. 5 in reference[11]. This structural transformation occurs at a minimum substrate temperature of 425° C. Quoting from their paper, “The evolution of the hydrogen-terminated RHEED pattern from the 1×1, as loaded to the 2×1 (sic) at approximately 425° C., is the same as our standard full thickness wafer cleaning procedure. The diffuse electron scatter between the lines reduces and the lines become sharper and more pronounced with low-temperature or normal temperature Si growth.”

Whereas Eaglesham et al. reported epitaxial growth of silicon at 380° C. using a low temperature cleaning process, this temperature is below the threshold for thermal desorption of hydrogen, and they conclude that epitaxial growth is only possible at such low temperatures because of structural disorder in the silicon surface produced by their low temperature cleaning method [8]. Structural disorder in the surface enhances the chemical reactivity of the silicon surface without requiring complete desorption of hydrogen. Atomically flat, hydrogen-terminated Si(100) surfaces are typically characterized by a dihydride structure, in which each silicon atom on the surface is bonded to two hydrogen atoms. Epitaxial growth of self-ordered 2D-doped silicon requires a transformation of the surface structure from the disordered state produced by low temperature cleaning into a highly ordered, atomically flat surface. This transformation must be accompanied by desorption of hydrogen. According to both MIT-LL [12] and Grunthaner et al [7], thermal desorption of hydrogen requires a minimum temperature of approximately 425° C., corresponding to a transformation of the dihydride-terminated 1×1 surface phase to a monohydride-terminated 2×1 surface phase.

From 1988 to the present, growth temperatures greater than the 425° C. required to induce this structural transformation of the silicon surface have been considered essential in order to achieve high quality epitaxial growth on silicon devices, even for the Sb delta-doping process which calls for reducing the substrate temperature after initiating growth [13]. The present disclosure describes a process that surprisingly overcomes the above significant challenges in reducing the growth temperature used for fabricating silicon devices. Applicant's process comprises growing delta-doped silicon at temperatures below 425° C. by leveraging dopant-induced catalysis to induce a phase transformation of hydrogen-terminated Si(100) surfaces from the as-cleaned disordered state characterized by a 1×1 RHEED pattern to the ordered state characterized by a 2×1 RHEED pattern that is required for high quality epitaxial growth.

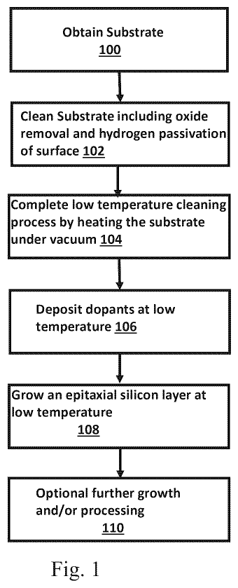

FIG. 1 is a flow chart illustrating a method of fabricating a device such as a detector. Note that some steps may be added, altered, eliminated, or performed in a different sequence, depending on specific requirements for different detector designs.

Block 100 represents obtaining a substrate.

In one embodiment, the substrate may disposed on a support substrate used to support the substrate during a thinning process. In one example, the thinning process is a frame-thinning process in which thinning leaves a thick frame to support the thinned region. In another embodiment, the substrate is bonded toa mechanical support prior to thinning in order to thin the entire device wafer. The step may comprise planarization and oxide-oxide bonding of the substrate to the support wafer. In one embodiment, the substrate comprises a detector with circuitry, and the support comprises additional circuitry such as, but not limited to, readout circuitry for CMOS/CCD devices.

The step may optionally comprise cleaning the surface to be thinned, for example, using a standard cleaning process for silicon wafers, such as the RCA cleaning process.

The step may then further comprise thinning the substrate to expose a device surface, e.g., the detector epilayer for back illumination. The thinning process may include for example, a series of steps including chemical-mechanical polishing (CMP), chemical etching with a heated KOH solution, chemical etching with a mixture of hydrofluoric and acetic acids, and etching with a solution of KMnO₄. In one embodiment, the steps comprise a grinding process for coarse thinning, followed by a chemical etch to selectively remove the highly-doped silicon substrate. The chemical etch may be a hydrofluoric, nitric, acetic (HNA) etch. The HNA etch may include a ratio of 1:3:8 HF:HNO₃:H₂O. After substrate removal, a planarization process such as a CMP may remove additional silicon, leaving the wafer with a uniform, mirror finish with nanometer-scale surface roughness.

Block 102 represents preparing the substrate for growth. The process for manufacturing the substrate in Block 100 may introduce damage and contaminants on the detector surface that must be removed in the Block 102 surface preparation process. The preparation process may comprise cleaning the back surface of a thinned detector (i.e, the surface for subsequent epitaxial growth), to remove organic and metallic contaminants (e.g., including, but not limited to, carbon, oxygen, metal atoms that can form charge traps for mobile electrons or holes used in the functioning of the device). The cleaning process may include an etching step to remove subsurface damage and contaminants. These cleaning steps may be followed by a UV ozone cleaning process to remove residual carbon contamination, and a spin-clean process using hydrofluoric acid (HF) to remove the native oxide and terminate the surface with hydrogen. The final surface preparation steps prior to growth may be performed in a nitrogen-purged glove box.

In one embodiment, the process comprises a piranha clean of the planarized surface. The piranha clean process may be wet etch process including a 3:1 mixture of sulfuric acid and 30% hydrogen peroxide. The process further includes performing a slight etch to the piranha-cleaned surface. The slight etch can be a Takizawa's slight etch process comprising a wet etch with nitric acid including a trace volume of hydrofluoric acid. The process may further includes performing an ammonium fluoride etching step to the slight etched surface to form an atomically flat silicon (100) surface in which subsurface damage and contamination are significantly reduced.

The preparation step must include hydrogen passivation of the surface (e.g., after cleaning), for example, by placing the detector on a spinner in a nitrogen environment and exposing the surface to a sequence of chemicals while spinning including ethanol, an HF:ethanol mixture, and ethanol again.

Block 104 represents loading the substrate into a reactor for epitaxial deposition of dopants. The step may comprise loading the device into a vacuum chamber of a reactor for epitaxy (e.g., MBE) and pumping to ultrahigh vacuum pressures, transferring the device under vacuum into the growth chamber, and optionally annealing the device at low temperature to remove volatile chemicals from the surface, for example, by heating to 150° C. for at least 10 minutes.

Block 106 represents heating the substrate to a temperature, e.g., of below 425° C. to epitaxially deposit a layer or sub-monolayer of dopants. As used herein, epitaxial deposition is such that dopants occupy lattice sites on the (001) crystal surface of the cleaned substrate without a buffer layer. The dopants may be deposited as 2D delta-doped layers so as to 2D dope the silicon (001) surface. Example temperatures include, but are not limited to one or more temperatures (T) less than or equal to 400° C., less than or equal to 370° C., or less than or equal to 350° C., e.g., in a range of 250° C.≤T<400° C., 250° C.≤T≤350° C., 250° C.≤T≤370° C., or 250° C.≤T≤380° C. or 250° C.≤T<425° C. The dopants may form bonds with the silicon so as to facilitate desorption of hydrogen from the (001) surface. The desorption may transform the dihydride surface into a monohydride surface suitable for epitaxial silicon growth. The dopants (acceptors or donors) may passivate the charge traps introduced by the contaminants or defects at the (001) surface (e.g., residual damage or contaminants that remain on the surface after low temperature cleaning or preparation steps in Blocks 100-102). For example, a p-type dopant may accept an electron charge from a contaminant, thereby compensating a positively charged trap state with a negatively charged ionized dopant. In another embodiment, an n-type dopant may donate an electron to a contaminant, thereby compensating a negatively charged trap state with a positively charged ionized dopant.

Block 108 represents performing epitaxial growth of silicon on the dopant layer, e.g., at a temperature below 425° C. The deposition is such that the silicon encapsulates the dopants, so as to prevent movement or segregation of the dopants away from the (001) surface or interface with the substrate. don't move or segregate, stay at or near interface

Example temperatures include, but are not limited to one or more temperatures (T) less than or equal to 400° C., less than or equal to 370° C., or less than or equal to 350° C., e.g., in a range of 250° C.≤T<400° C., 250° C.≤T≤350° C., 250° C.≤T≤370° C., or 250° C.≤T≤380° C. or 250° C.≤T<425° C.

Block 110 represents optionally further growth and processing.

Further growth may comprise performing iterative growth of a plurality of delta-layers: For each delta-layer in the multilayer, the growth comprises depositing dopant atoms until the desired dopant density is reached, stopping the flux of dopant atoms, and growing a desired thickness of silicon over the delta-layer. For example, a dopant density of at least 10¹⁴ cm⁻² and a silicon layer thickness, e.g., between 0.5 and 2 nm may be used for each delta-layer. It is not required that each layer be identical to the previous layer.

Growth of 2D-doped silicon may proceed by alternately depositing silicon and dopant atoms, using shutters to control the source fluxes. The shutters may control sources such that the decontaminated surface is alternately and contacted with a source including silicon and a source including dopants. The atomically abrupt “delta-doped” structure may be formed by closing the silicon shutter and opening the dopant shutter in order to deposit a fraction of a monolayer of dopant atoms on the atomically-flat silicon surface. Once this layer is formed, the dopant shutter may be closed and the silicon shutter may be opened to resume epitaxial growth of silicon.

In one embodiment, this process creates epitaxial silicon layers comprising one or more delta-doped layers wherein the dopant is confined to only a few atomic layers. Under these conditions, silicon and dopant atoms are integrated into the silicon lattice, forming an epitaxial layer of silicon with exceptionally high concentration of dopants with close to 100% electrical activation.

After growth, the step comprises cooling the device gradually and removing from the reactor vacuum chamber.

Optional further steps may include oxide formation and antireflection coating, as necessary for specific applications, or formation of electrical contacts.

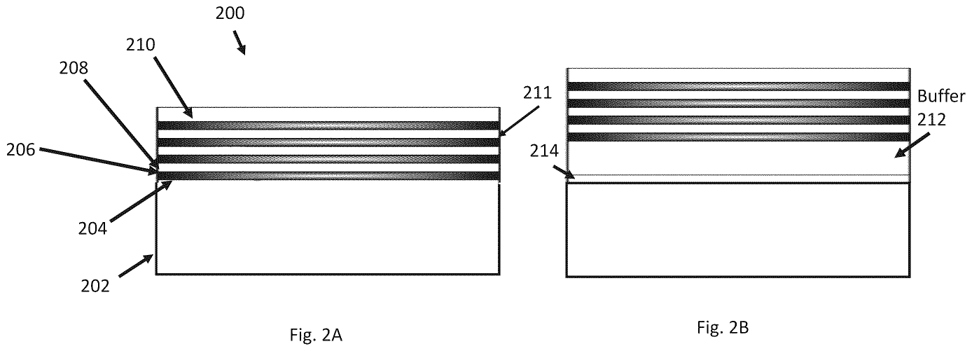

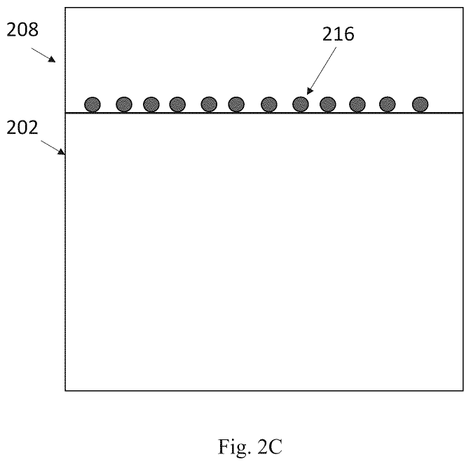

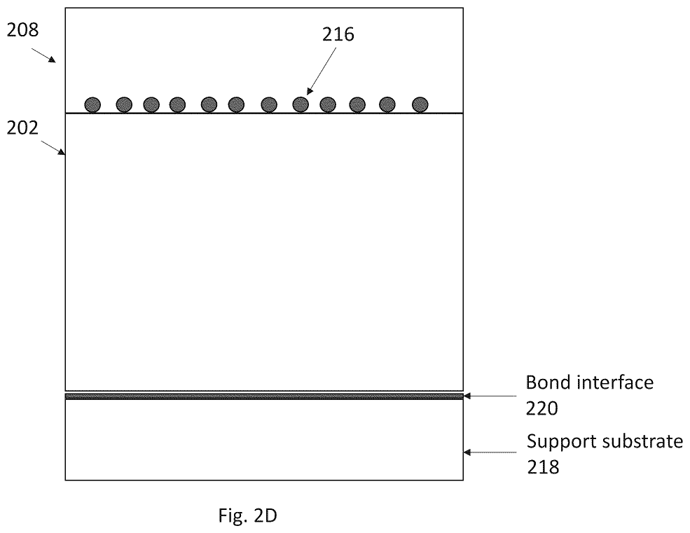

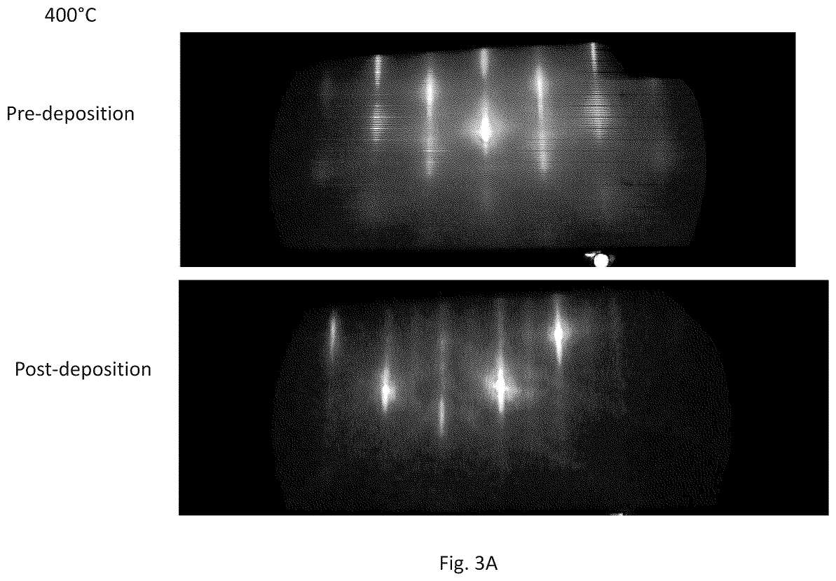

FIG. 2A illustrates the end result of the method, a passivated silicon structure 200, comprising a substrate 202 comprising a silicon (001) surface 204, a layer 206 of dopants in direct physical contact with the silicon (001) surface (e.g., 0.5 ML of dopants deposited directly on substrate surface at low temperature in Block 106); and a crystalline silicon layer 208 epitaxially grown directly on the silicon (001) surface (grown at low temperature in Block 108) and encapsulating the dopants. In the example shown, the a further crystalline silicon layer comprises one or more delta-doped layers 210 (optional and also grown at low temperature below 425° C. as for layers in Block 106 and 108). The dopants (acceptors or donors) provide a charge that passivates the charge traps introduced by the contaminants or defects at the (001) surface. In some embodiments, the substrate is further processed with circuitry or combined with other substrates, e.g., to form a back thinned detector. The passivated silicon structure is differentiated from previous structures where the epitaxial silicon layer is deposited on a substrate via a buffer layer 212 comprising epitaxially grown silicon, as illustrated in FIG. 2B. In FIG. 2B, the substrate-epilayer interface 214 between MBE silicon and substrate silicon contains defects and contaminants from the cleaned surface, leading to the presence of unpassivated traps. The passivated silicon structure according to the present invention grows the dopants directly on the cleaned (001) surface without a buffer layer/nucleation layer.

FIG. 2C illustrates how the silicon layer can encapsulate the dopants 216 in the dopant layer. The dopant atoms 216 can have a coverage that passivates the charge traps introduced or defects at the (001) surface 204 between the substrate 202 and subsequently epitaxially grown layers, and/or that creates an atomically flat monohydride terminated surface suitable for the low temperature growth of delta-doped or multilayer-doped silicon. In one embodiment, 10 atomic layers of silicon (approx. 1.5 nm) are grown on the sub monolayer dopant layer (1-2 atomic layers) in order to encapsulate the dopants.

FIG. 2D illustrates a configuration wherein the passivated silicon structure 200 is bonded to a support substrate 218 at a bond interface 220. Optional circuit layers 222 for a device including the passivated silicon structure can be on either the same or opposite side of the epitaxially grown silicon substrate 202. Optional circuit layers (not shown) for a device including the passivated silicon structure can be on one or both sides of the bond interface 220. A 3D stacked wafer can be formed with circuits on both sides of the interface (on backside of the passivated silicon structure and on the support substrate). A back thinned CCD detector can be formed with circuit formed on one side of the interface (on the substate side of the passivated silicon structure). The circuits can be formed in a thin layer, e.g., several microns thick.

Using Optional selective area growth, circuits can be formed on the same side as the passivated layer.

### Growth Procedure

In some embodiments, a computer-controlled MBE system is equipped with a robotic system for automated transfer of wafers under ultra-high vacuum (UHV) between a cluster chamber and a separate growth chamber may be utilized to produce the delta-doped CCDs. These production-scale molecular beam epitaxy (MBE) systems may process 150 mm and 200 mm silicon detector wafers with high throughput and high yield.

In one embodiment, up to eight wafers may be loaded at a time into the MBE system. Detector wafers may be placed face-down on 10 inch platens and loaded into an elevator in the introduction chamber of the MBE system. The introduction chamber may then be evacuated using a clean cryopump system, and wafers may be robotically transferred into a UHV cluster chamber, where they are loaded into an 8-position elevator for temporary storage. Wafers may be transferred one at a time into a separate UHV chamber for MBE growth. The MBE growth chamber may be equipped with a radiative substrate heater for controlling the wafer temperature, an e-beam source for deposition of silicon, and multiple effusion cells for deposition of dopants. All sources may be equipped with shutters. Epitaxial growth of 2D-doped silicon may be performed by controllably heating the wafer to between 300° C. and 400° C. when the dopants are deposited as described herein to catalyze transformation of the atomic structure of the silicon surface from di-hydride to monohydride termination of silicon, which are conditions for epitaxial growth of silicon.

The above method differs from conventional methods in that the device is kept below 425° C. at all times from block 102-108, from cleaning and loading into the reactor to unloading from the reactor. The growth and fabrication temperature as described herein are expected to improve manufacturability, yield, and performance by reducing or eliminating delamination of detector wafers during MBE growth. Delamination occurs when gas bubbles form at the interface between the detector wafer and the supporting wafer and higher temperatures increase the risk of delamination. Performance may also be improved because high temperatures above 400° C. can cause “de-passivation” of traps at the Si—SiO₂ interface underneath MOS gates in the detector wafer, which can lead to increased dark current and persistence in silicon detectors.

In a later refinement to their process, MIT-LL reported that MBE growth at 450° C. causes MBE-passivated detectors to suffer from increased dark current, which they addressed by sintering their detectors in hydrogen for 30 minutes at 400° C. [14]. A benefit of this disclosure is the reduction of the process temperature to less than 425° C., which obviates the need for post-growth sintering at 400° C.

Process temperatures greater than 400° C. are known to cause an increased risk of structural damage in back-illuminated silicon CCDs and CMOS image sensors, especially in detectors that have been fabricated using oxide-oxide bonding and thinning processes [15]. Bonding and thinning processes are commonly used in the semiconductor industry to manufacture back-illuminated CCDs and CMOS image sensors, including state-of-the-art 3D-stacked silicon circuits comprising a silicon detector bonded to a silicon readout integrated circuit (ROIC). A benefit of the present disclosure is the reduction of the maximum process temperature to reduce the risk of structural damage, thereby improving manufacturing yields and reducing costs.

### The Role of Hydrogen in Silicon MBE

Low temperature MBE, which is essential for some applications of silicon detectors, requires the removal of the native oxide layer from the silicon surface. Some processes are based on the HF spin-clean method developed by Grunthaner et al., which results in the formation of a hydrogen-terminated silicon surface suitable for low temperature MBE growth [7].

Hydrogen plays an essential role in silicon molecular beam epitaxy [16,17]. There are important subtleties in the chemistry of hydrogen on silicon surfaces that impose thermal requirements on the process. Hydrogen-terminated silicon can exist in two different phases [18]. The oxide-removal process that enables low temperature silicon MBE induces the formation of dihydride surface phase, which is characterized by a 1×1 surface reconstruction. When the silicon substrate is heated in an ultrahigh vacuum chamber to a temperature between 640K and 700K (˜370° C. to 430° C.), the silicon surface undergoes a thermally-induced transformation from a dihydride phase (SiH₂) to a monohydride phase surface (SiH) [19].

This phase transformation of chemisorbed hydrogen on the silicon surface is critical to initiating the epitaxial growth of silicon, and explains conventional techniques using a substrate temperature greater than 425° C. for silicon MBE growth on silicon detectors [12]. The phase transformation of chemisorbed hydrogen is accompanied by a change in the surface reconstruction from a 1×1 to a 2×1 pattern, which can be observed in situ during MBE growth by using reflection high energy electron diffraction (RHEED). In conventional techniques, once the surface has undergone this phase change and epitaxial growth has been initiated, the substrate temperature can be reduced and epitaxial growth can be continued at a significantly lower temperature. Such a reduction of temperature is often necessary to facilitate incorporation of dopants into substitutional sites on the silicon lattice and avoid problems with segregation of dopants to the surface. At the same time, there is a constraint on the minimum growth temperature, in the first place for dopants to be electrically active upon incorporation into the lattice [20], and in the second place to maintain layer-by-layer crystalline growth in light of a temperature-dependent limiting thickness for epitaxial growth of silicon [21].

### Boron Induced Phase Transformation of Hydrogen Terminated Si(100)

The delta-doping methods that have been developed are all heavily dependent on the chemistry and dynamics of silicon and dopant adatoms on silicon surfaces during the growth process. Critical to all of these processes is the role of hydrogen on the silicon surface. As discussed above, silicon MBE cannot be initiated on the dihydride phase of hydrogen-terminated silicon. The thermally-induced transformation of hydrogen-terminated silicon from the dihydride to monohydride phase requires a minimum temperature of 370° C., which is why low temperature silicon MBE has traditionally been limited to this temperature.

The method described herein uses dopants such as (but not limited to) boron to induce a phase transformation on the silicon surface in order to initiate epitaxial growth at temperatures below the previously-recognized minimum temperature of 370° C. Inspiration for the doping procedure was drawn from work by researchers at Sandia National Laboratories on precision doping of silicon using gas-phase reactions. Frederick et al. described a method for ultradoping of silicon with boron using solvothermal chemistry wherein “an integral part of the gas-phase ultradoping process is a direct chemical bond between dopant and Si which enables low-temperature dopant incorporation” and the “unprecedented dopant levels” achieved by ultradoping were said to “transform [silicon's] electronic behavior and enable its use as a next-generation electronic material.”[22] Campbell et al. describe methods for p-type doping of Si(100)-2×1 using diborane [23,²⁴].

Ultradoping can be defined a doping process that fundamentally changes the electronic behavior of Si, causing the band structure of the material to be determined by the electrons confined in the dopant layer rather than by the properties of the parent material. This behavior is believed to be due to overlapping electronic structures of the confined dopants which allow coherent electronic transport from dopant to dopant without having to interact with the host material. In order to form the quantum behavior that distinguishes ultradoping and delta-doping from conventional “3D” doped silicon (e.g., surfaces doped using conventional methods of ion implantation and/or diffusion), three requirements must be met. (1) dopant atoms must occupy substitutional sites in the silicon lattice in order for the dopants to be electrically active; (2) dopant atoms must comprise an ordered 2D structure in the silicon crystal wherein dopant atoms are confined to one or a few monolayers in the silicon crystal and do not occupy adjacent lattice sites (aka clustering); and (3) silicon must be grown epitaxially on top of the delta-doped layer in order to stabilize and protect the delta-layer. With respect to the physics of delta-doped silicon, the essential requirement is to achieve an exceptionally high density of electrically active dopants (in the range of 10²¹ to 10²² cm⁻³). Dopant densities in this range far exceed the solid solubility limits of 3D-doped silicon.

Frederick et al. [22] developed a process that uses an overnight exposure of the silicon surface to a liquid benzene solution containing an azobisisobutyronitrile (AIBN) catalyst. Unfortunately the catalyst reacted chemically with the silicon surface, leading to a significant presence of C, O and N contaminants on the surface. Although they were able to incorporate boron into the silicon surface at low temperatures, the contaminants make it unsuitable for use on silicon devices. Moreover, they only got as far as demonstrating the presence of Si—B bonds and did not demonstrate a process for encapsulating and protecting the boron-doped surface with crystalline silicon. Although Campbell et al. and Škereň et al. describe a gas-phase process for fabricating delta-doped devices by exposing the silicon surface to diborane at temperatures as low as 200° C., their diborane process requires the use of a scanning tunneling microscope to transform the silicon surface from dihydride- to monohydride-termination at low temperatures, and they have to anneal their detectors to 510° C. after growth in order to achieve electrical activation of the boron dopants. Despite the importance of their process for demonstrating the possibility of atomic precision advanced manufacturing (APAM), their process requires a high temperature anneal and their use of a scanning tunneling microscope means that their process is not viable or practical for manufacturing very large scale integrated (VLSI) circuits and detectors, such as back-illuminated CCDs and CMOS image sensors.

Without being bound to a specific scientific theory, the deposition of elemental boron on hydrogen-terminated silicon will result in the formation of B—Si bonds necessary for delta-doping, and the consequent transformation of the Si(100)-1×1 surface to a Si(100):B−2×1 surface is suitable for overgrowth of epitaxial silicon at temperatures below 425° C. Thus, ultralow temperature growth of boron-delta-doped silicon is a viable approach for low temperature MBE growth of epitaxial silicon.

A similar dopant-induced surface chemistry may be expected to enable growth of Sb-delta-doped silicon at ultralow temperatures. Atomic antimony deposited on an Si(100):H−1×1 surface under UHV conditions will likely react with hydrogen to form SbHx species on the surface. For the purposes of low temperature MBE growth, the important question is whether subsequent reactions of SbHx with the surface will result in the formation of Si—Sb bonds and the evolution of hydrogen from the surface.

Rodríguez-Reyes and Teplyakov cite multiple sources showing that ammonia (NH₃) deposited on Si(100):H surfaces under similar conditions will thermally decompose and insert itself into the Si—Si bond, with nitrogen eventually undergoing subsurface migration to the third or fourth layer of the silicon lattice [25]. Although similar studies have not been performed with antimony, subsurface migration of antimony is less likely because of its larger atomic size, and it is likely that reaction pathways exist for elemental antimony to bond to the surface in electrically active sites and also to catalyze the phase transformation on the silicon surface as described for Boron.

### Experimental Results

The ultralow temperature delta doping processes described herein can follow previously-developed processes for surface preparation and growth, up to the point of initiating epitaxial growth. Whereas previously the substrate would be heated to temperatures in the 400-425° C. range before initiating growth by depositing a silicon buffer layer, in the new process described herein, the substrate is heated to a temperature below the 425° C. threshold temperature and growth is initiated by depositing dopant atoms on the surface (e.g., directly on the surface without a buffer layer).

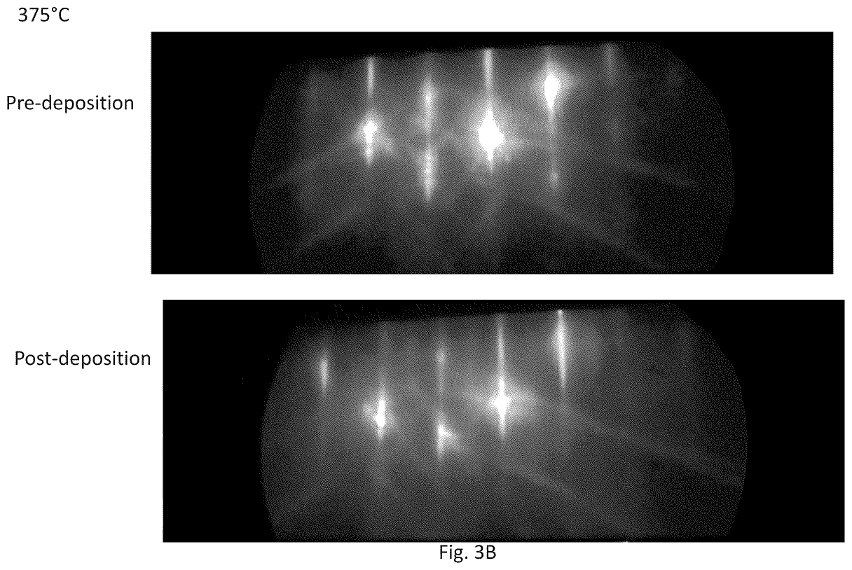

Either p-type dopants, such as boron, or n-type dopants, such as antimony or phosphorous can be used. The RHEED data in FIG. 3 presented herein confirms the hypothesis that the dopant atoms interact chemically with the hydrogen-terminated silicon surface, catalyzing the transformation of the surface from the dihydride to the monohydride phase, thereby enabling epitaxial growth of silicon at temperatures below 425° C. or below 400° C.

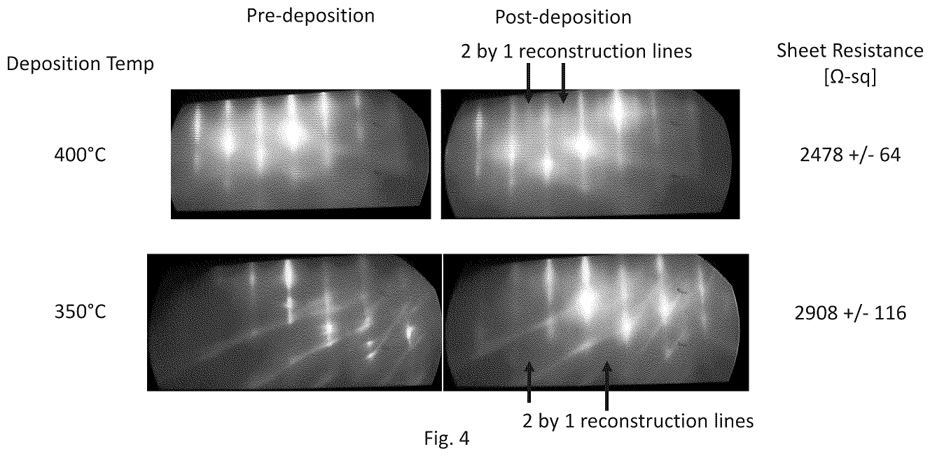

Upon reaching a surface coverage of dopant atoms sufficient to complete the phase transformation, epitaxial growth was initiated by depositing silicon on the surface. Epitaxial growth was confirmed by using RHEED to monitor electron diffraction from the silicon surface and evidence crystalline silicon with monolayer doping at ultralow temperatures, as shown in FIGS. 3A-3B and FIG. 4. The RHEED measurements prior to the dopant layer deposition show 1×1 RHEED characteristic of dihydride terminated surface. By the end of growth at 350° C. or 375° C. (after deposition of the dopant layer and the silicon layer), FIG. 4 and FIG. 3B respectively show that new higher order diffraction orders of twice the lattice constant appear between the 1×1 spots, which is characteristic of the 2×1 reconstructed surface. At 350° C., the RHEED pattern exhibits Kikuchi lines which is a good indication of crystallinity. Characteristics of amorphous growth such as the pattern of lines changing first to spots (as the surface transitions from 2D to 3D) and then to rings (fully amorphous) is not observed, further supporting the epitaxial crystalline growth at the temperature of 350° C.

Electrical characterization was performed using a noncontact method to map the surface conductivity, showing the dopants are electrically active and sheet resistance not significantly reduced for the growth at the temperature of 350° C. as compared to that at 400° C. (results shown in Table 1). This electrical characterization further evidences that the growth of silicon at 350° C. is crystalline.

### Experimental Procedure

1. The following substrates were loaded into a MBE reactor for two different experiments:
A high resistivity substrate having a 150 mm diameter with resistivity >10,000 Ohm and 15<100> orientation (Experiment 1).‘
A low resistivity substrate having 100 mm diameter with resistivity 0-100 ohm-cm and <100> orientation,

2. The substrate was heated according to the following profile:
Heat to 150° C. at 15° C./min.
Soak at 150° C. for 10 minutes (minimum).
Heat to deposition temperature at 15° C./min.
Allow to stabilize to +/−2° C. of setpoint

3. Boron was deposited for 13 min (780 s); with a dose of 0.5 ML<dose<1 ML.

4. Silicon was deposited for 10 nm; 0.3 Å/s.

TABLE 1

| | Substrate | Sheet Resistance | |
|---|---|---|---|
| Sample ID | Temp [° C.] | [Ohm-sq] | Note |
| Substrate (out of | n/a | >50k | Out of range for |
| box) | | | LEI (>4 kΩ-sq) |
| Ulow 20241021_b | 400 | 2478 +/− 64 | 55-pt wafer map |
| Ulow 20241021_a | 350 | 2908 +/− 116 | 55-pt wafer map |

### Example Devices

FIG. 2A illustrates a general passivated silicon structure useful in a variety of devices. Although many illustrative examples are provided in the context of detectors, the fabrication methods described herein are applicable to any silicon device with metal oxide contacts such as integrated circuits (e.g., comprising gates, transistors) with oxide at interfaces where the passivation of the interface is needed for optimal device performance. Passivation is enabled by (1) the low temperatures during all fabrication steps preventing de-passivation of traps, (2) passivation of contaminants by colocation of the dopants directly on the contaminants of the (001) silicon surface after cleaning, (3) optional passivation of oxidized surfaces by 2D delta doping, and/or (4) optional quantum exclusion isolating photogenerated carriers from surface traps using the delta doping layers. Low temperatures also prevent delamination of the passivated silicon structure from a support substrate in devices with bonded interfaces.

FIG. 5 is a cross sectional view of an image sensor 500 produced utilizing the process described in FIG. 1 in accordance with an embodiment of the invention. As illustrated, the image sensor includes a detector. The detector includes a back thinned detector surface for receiving electromagnetic radiation 502 and a bulk silicon wafer 504. The detector comprises the passivated silicon structure formed utilizing the process described in FIG. 1 and FIG. 2A. As described herein, an epitaxial growth process described in FIG. 1 is utilized to grow first a dopant layer 206 and then a 2D-delta doped silicon 210 on the detector surface 202. As discussed previously, the back thinning process and cleaning process produces contaminants which affect the performance of the detector and which may be passivated using the dopants as described herein. The detector 500 may include a CCD front side circuitry for collecting the photogenerated carriers generated by the electromagnetic radiation.

In another embodiment, using selective area growth, circuits can be formed on the same side as the passivated layer (side of device with epilayer 210, 206 from which electromagnetic radiation 502 is incident), e.g., a different location on the surface from the passivation.

In typical examples illustrated in FIG. 2A, the device has multilayer doping according to principles of the invention. 0. Layers 206, 208, 210 are grown on the thinned wafer. In the example illustrated, layers 210, presented in partially darkened fill, represent four doped layers that include a density of a deliberately added dopant species (such as a p-type dopant such as boron, or an n-type dopant such as phosphorus or antimony). The wafer need not have exactly four doped layers, but in general a plurality M of doped layers, where M is an integer greater than 1. The dopant sheet densities in the M doped layers need not be the same, but in principle can be selected to be the same sheet densities or to be different sheet densities. Interleaved between layers 210 are M−1 (here with M=4, M−1=3) layers of silicon 211 that are not deliberately doped (also referred to as “undoped layers”), for example, layers that are substantially silicon having no deliberately added dopant. Structures with M=2, M=3 and M=4 have been demonstrated. Layer 211 may be doped as desired or as may be convenient. In general, the plurality of M doped layers 210 can be as thin as a single layer of silicon (approximately 2.5 Angstroms) and can be doped at sheet densities up to approximately 2×10¹⁴ cm⁻² dopant atoms. One way to measure dopant density is sheet density, which is measured in dopant atoms per square cm. The M−1 layers 211 that are not deliberately doped can have thicknesses in the range of 5 Angstroms to 40 Angstroms, and are preferably grown with thicknesses in the range of 10 Angstroms to 30 Angstroms.

### Advantages and Improvements

The present disclosure has discovered that depositing dopant atoms on a dihydride surface enables MBE growth of crystalline silicon at lower temperatures than were previously possible. It is believed that the deposition of dopants triggers desorption of hydrogen from the dihydride surface to form a monohydride surface, using a much lower surface density of dopants than would be required to bond to all the silicon atoms that were released from the hydrogen bonds. The RHEED data shows that 2D-doped silicon was successfully grown on a dihydride surface, with a change from 1×1 (dihydride) surface to a 2×1 (monohydride) surface during the growth. Resistivity measurements show that the 2D-doped silicon grown at 350° C. is highly doped and electrically conductive, comparable to 2D-doped silicon grown at 400° C.

### REFERENCES

The following references are incorporated by reference herein.
[1] Hoenk, M. E., Grunthaner, P. J., Grunthaner, F. J., Terhune, R. W., and Hecht, M. H., “Growth of delta-doped layers on silicon CCDs for enhanced ultraviolet response,” U.S. Pat. No. 5,376,810 (1994).
[2] Hoenk, M. E., “Surface Passivation by Quantum Exclusion Using Multiple Layers,” U.S. Pat. No. 8,395,243, issued Mar. 12, 2013.
[3] Hoenk, M. E., “Surface Passivation by Quantum Exclusion Using Multiple Layers,” U.S. Pat. No. 9,024,344, continuation in part, issued May 5, 2015.
[4] Hoenk, M. E.; Nikzad, S.; Jones, T.; Greer, H. F.; Carver, A., “Delta-doping at Wafer Level for High Throughput, High Yield Fabrication of Silicon Imaging Arrays,” U.S. Pat. No. 8,828,852, issued Sep. 9, 2014.
[5] Citrin, P. H., Muller, D. A., Gossmann, H.-J., Vanfleet, R. and Northrup, P. A., “Geometric Frustration of 2D Dopants in Silicon: Surpassing Electrical Saturation,” Phys. Rev. Lett. 83: 3234 (1999).
[6] Citrin, P. H., Muller, D., Gossmann, H.-J., Vanfleet, R. and Northrup, P. A., “Breaking through the electrical saturation barrier: 2D- versus 3D-doping in n-type silicon,” Physica B 273-274: 251-255 (1999).
[7] Grunthaner, P. J., Grunthaner, F. J., Fathauer, R. W., Lin, T. L., Hecht, M. H., Bell, L. D., Kaiser, W. J., Schowengerdt, F. D., and Mazur, J. H., “Hydrogen-terminated silicon substrates for low temperature molecular beam epitaxy,” Thin Solid Films, 183: 197-212 (1989).
[8] Eaglesham, D. J., Higashi, G. S., and Cerullo, M., “370° C. clean for Si molecular beam epitaxy using a HF dip,” Appl. Phys. Lett. 59(6): 685-687 (1991).
[9] Gossmann, H.-J.; Schubert, E. F.; Eaglesham, D. J.; Cerullo, M., “Low-temperature Si molecular beam epitaxy: Solution to the doping problem,” Appl. Phys. Lett. 57, 2440-2442 (1990); https://doi.org/10.1063/1.103870
[10] Headrick, R. L.; Weir, B. E.; Levi, A. F. J., Freer, B., Bevk, J., and Feldman, L. C., “Ordered monolayer structures of Boron in Si(111) and Si(100),” J. Vac. Sci. Technol., A 9(4): 2269-2272 (1991).
[11] Headrick, R. L.; Weir, B. E.; Levi, A. F. J.; Eaglesham, D. J.; and Feldman, L. C., “Si(100) (2×1) boron reconstruction: Self-limiting monolayer doping,” Appl. Phys. Lett. 51 (26): 2779-2781, 24 Dec. 1990.
[12] Calawa, S. D.; Burke, B. E.; Nitishin, P. M.; Loomis, A. H.; Gregory, J. A.; Lind, T. A., “Substrate preparation and low-temperature boron doped silicon growth on wafer-scale charge-coupled devices by molecular beam epitaxy,” J. Vac. Sci. Technol. B 20(3): 1170-1173, 2002; https://doi.org/10.1116/1.1477200
[13] Jewell, A. D., Hoenk, M. E., Carver, A. G., and Nikzad, S., “Low-temperature homoepitaxial growth of two-dimensional antimony superlattices in silicon,” Journal of Vacuum Science and Technology A 36, 061513 (2018). https://doi.org/10.1116/1.5040837
[14] Westhoff, R. C.; Rose, M. K.; Gregory, J. A.; Berthiaume, G. D.; Seely, J. F.; Woods, T. N.; Ucker, G., “Radiation-hard, charge-coupled devices for the extreme ultraviolet variability experiment,” Proc. SPIE 6686, UV, X-Ray, and Gamma-Ray Space Instrumentation for Astronomy XV, 668604 (12 Sep. 2007); https://doi.org/10.1117/12.734371
[15] Hoenk, M. E., Jewell, A. D., Kyne, G., Hennessy, J., Jones, T., Cheng, S., Nikzad, S., Morris, D., Lawrie, K., and Skottfelt, J. “2D-doped silicon detectors for UV/optical/NIR and x-ray astronomy,” SPIE Proc. 12191, X-Ray, Optical, and Infrared Detectors for Astronomy X; 1219113 (2022) https://doi.org/10.1117/12.2631542
[16] Vasek, J. E., Zhang, Z., Salling, C. T., and Lagally, M. G., “Effects of hydrogen impurities on the diffusion, nucleation, and growth of Si on Si(001),” Phys. Rev. B 51(23): 17207-17210 (1995).
[17] Sakamoto, K., Matsuhata, H., Miki, K., and Sakamoto, T, “Adsorption and desorption of atomic hydrogen on Si(001) and its effects on Si MBE,” Journal of Crystal Growth 157: 295-299 (1995).
[18] Sakurai, T. and Hagstrum, H. D., “Interplay of the monohydride phase and a newly discovered dihydride phase in chemisorption of H on Si(100) 2×1,” Phys. Rev. B 14(4): 1593-1596 (1976).
[19] Gupta, P., Colvin, V. L., and George, S. M., “Hydrogen desorption kinetics from monohydride and dihydride species on silicon surfaces,” Phys. Rev. B 37(14): 8234-8243 (1988).
[20] Headrick, R. L., Weir, B. E., Levi, A. F. J., Freer, B., Bevk, J., and Feldman, L. C., “Ordered monolayer structures of Boron in Si(111) and Si(100),” J. Vac. Sci. Technol., A 9(4): 2269-2272 (1991).
[21] Eaglesham, D. J., Gossman, H.-J., and Cerullo, M., “Limiting thickness hepi for Epitaxial Growth and Room-Temperature Si Growth on Si(100),” Phys. Rev. Lett. 65(10): 1227-1230 (1990).
[22] Frederick, E., Campbell, Q., Kolesnichenko, I. V., Peña, L. F., Benavidez, A, Anderson, E. M., Wheeler, D. R., and Misra, S., “Ultradoping Boron on Si(100) via Solvothermal Chemistry,” Chem. Eur. J. 27: 13337-13341 (2021). https://doi.org/10.1002/chem.202102200
[23] Campbell, Q., Ivie, J. A., Bussmann, E., Schmucker, S. W., Baczewski, A. D., and Misra, S., “A model for atomic precision p-type doping with diborane on Si(100)-2×1,” https://arxiv.org/pdf/2010.00129.pdf
[24]Škereň, T.; Köster, S. A.; Douhard, B.; Fleischmann, C.; Fuhrer, A. “Bipolar device fabrication using a scanning tunnelling microscope,” Nat. Electron. 2020, 1-7.
[25] Rodríguez-Reyes, J. C. F., and Teplyakov, A. V., “Role of surface strain in the subsurface migration of adsorbates on silicon,” Phys. Rev. B 78: 165314 (2008).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for fabricating a device, comprising:
(a) epitaxially depositing dopants on a (001) surface of a silicon wafer; and
(b) epitaxially depositing a crystalline silicon layer on the surface so as to encapsulate the dopants.

2. The method of claim 1, wherein the dopants and the silicon are deposited at a temperature below 425 degrees Celsius.

3. The method of claim 1, wherein the depositing in (a) and (b) is at a temperature of 400 degrees Celsius or less.

4. The method of claim 1, wherein the depositing in (a) and (b) is at a temperature of 370 degrees Celsius or less.

5. The method of claim 1, wherein the depositing in (a) and (b) is at a temperature of 350 degrees Celsius or less.

6. The method of claim 1, wherein at least 0.1 monolayer of the dopants are deposited on the (001) surface.

7. The method of claim 1, wherein at least 0.5 monolayer of the dopants are deposited ion the (001) surface.

8. The method of claim 1, wherein the dopants forms bonds with the silicon so as to facilitate desorption of hydrogen from the hydrogen-terminated silicon surface and/or passivate contaminants or defects on the (001) silicon surface.

9. The method of claim 1, wherein the (001) surface is a disordered or rough surface and the dopants are deposited directly on the disordered or rough surface.

10. The method of claim 1, wherein the dopants provide a charge that passivates the charge traps introduced by the contaminants or defects at or near the (001) surface.

11. The method of claim 1, further comprising depositing a plurality of the silicon layers alternating with layers of the dopants, so as to form a stack comprising multilayer delta doping.

12. The method of claim 11, wherein the device comprises a surface passivation layer entirely fabricated at a temperature below 425° C. and having a dark current that is reduced as compared that of the otherwise identical device fabricated using a temperature greater than 425° C.

13. The method of claim 1, further comprising passivating a plurality of devices on the silicon wafer at the temperature below 425° C., wherein the devices have the manufacturing yield greater as compared to the otherwise identical devices fabricated at a temperature greater than 425° C., wherein the greater yield includes less delamination of the silicon wafer from a support wafer present during the depositing.

14. The method of claim 1, wherein the dopants comprise p-type dopants for silicon (e.g., boron) or n-type dopants for silicon (e.g., antimony or phosphorous).

15. A passivated silicon structure, comprising:
(a) a substrate with a silicon (001) surface,
(b) a layer of dopants in direct physical contact with the silicon (001) surface; and
(c) a crystalline silicon layer epitaxially grown directly on the silicon (001) surface encapsulating the dopants.

16. The passivated silicon structure of claim 15, wherein the crystalline silicon layer comprises one or more delta-doped layers.

17. The passivated silicon structure of claim 15, comprising one or more devices.

18. The passivated silicon structure of claim 15, comprising a back-thinned silicon device.

19. The passivated silicon structure of claim 15, wherein the layer of dopants comprises at least 0.1 monolayer of the dopants.

20. The passivated silicon structure of claim 15, wherein the layer of dopants comprises at least 0.5 monolayer of the dopants.

21. The device of claim 15, wherein a surface density of the dopants passivates traps located near the substrate-epitaxial silicon interface.

22. The device of claim 15, wherein the silicon (001) surface is a disordered surface.
